(19) United States
(12) Patent Application Publication
(10) Pub. No.: US 2014/0111941 A1
(43) Pub. Date: Apr. 24, 2014

(54) ELECTRONIC DEVICE WITH COOLING MODULE

(71) Applicant: HON HAI PRECISION INDUSTRY CO., LTD., New Taipei (TW)

(72) Inventors: SHUN-SIANG TU, New Taipei (TW); LI-KAN YEH, New Taipei (TW)

(21) Appl. No.: 13/930,181

(22) Filed: Jun. 28, 2013

(30) Foreign Application Priority Data
Oct. 23, 2012 (TW) 101139050

(51) Int. Cl. H05K 7/20

(52) U.S. Cl. CPC H05K 7/20145
USPC 361/697; 361/695

(57) ABSTRACT

An electronic device includes a chassis and a cooling module. A plurality of air inlets and a plurality of air outlets are defined in a same side plate of the chassis. A partition separates the air inlets from the air outlets. Air flows into the chassis through the plurality of air inlets and flows out of the plurality of air outlets under the action of the cooling module, and then the electronic device is cooled.

### BACKGROUND

1. Technical Field

The present disclosure relates to electronic devices, and particularly to an electronic device with a cooling module.

2. Description of Related Art

Electronic devices, such as a personal computer or a notebook computer, defines a plurality air inlets in a first side plate of an chassis and a plurality of air outlets in a second side plate. The second side plate is adjacent to or opposite to the first side plate, and air flows into the electronic device from the air inlets and out of the electronic device through the air outlets. However, the chassis should be turned 90 angles or 180 angles when the air inlets and the air outlets are punched during manufacturing of the electronic devices, which is inconvenient and time-consuming. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device.

FIG. 2 is an assembled, isometric view of the electronic device of FIG. 1.

FIG. 3 is an exploded, isometric view of another embodiment of an electronic device.

FIG. 4 is an assembled, isometric view of the electronic device of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

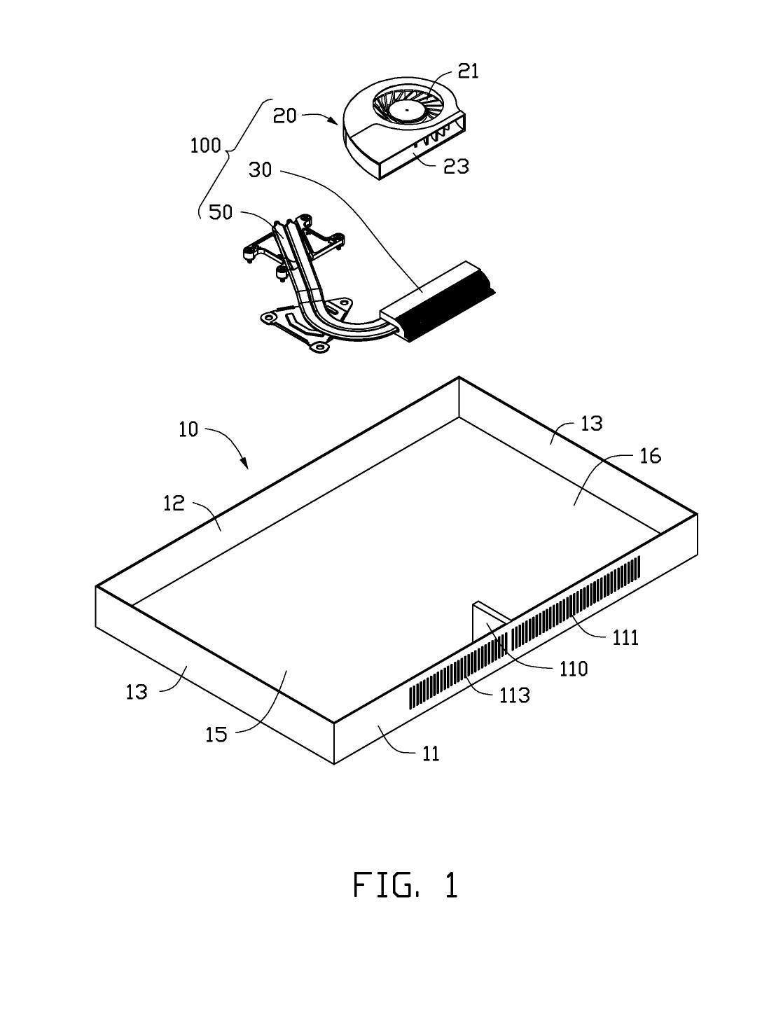

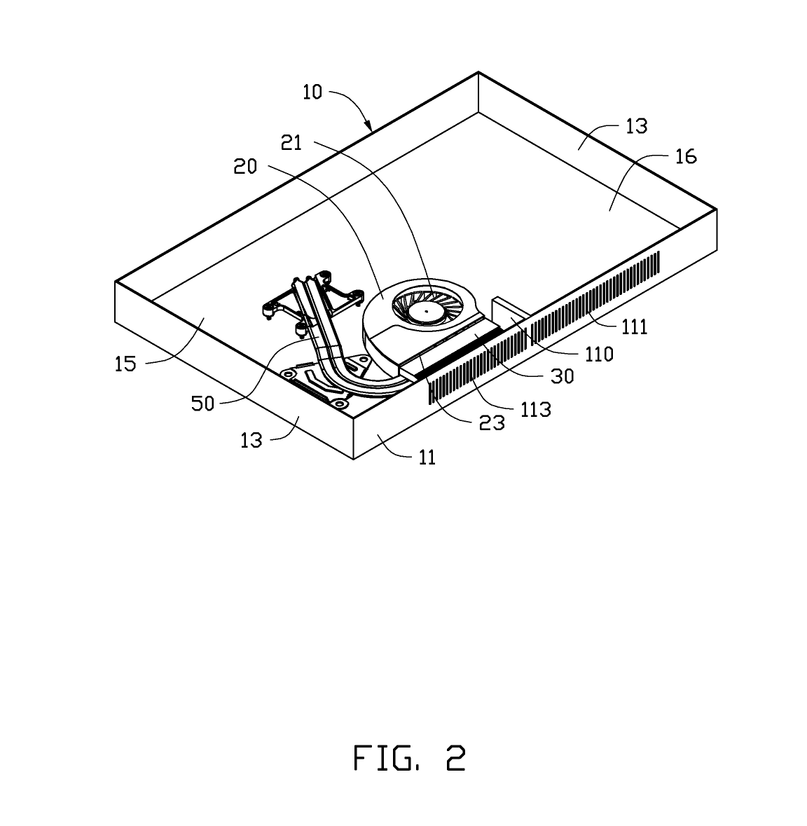

FIG. 1 and FIG. 2 show an electronic device in accordance with an embodiment. The electronic device includes a chassis 10 and a cooling module 100.

The chassis 10 includes a first side plate 11, a second side plate 12, two third side plates 13, and a bottom plate 15. The first side plate 11, the second side plate 12, and the two third side plates 13 perpendicularly extend from four edges of the bottom plate 15. In one embodiment, the first side plate 11 is substantially parallel to the second side plate 12 and each of the two third side plates 13. A receiving space 16 is defined cooperatively by the first side plate 11, the second side plate 12, and the two third side plates 13. The receiving space 16 is used for receiving electronic components, such as the cooling module 100 and a circuit board (not shown).

A partition 110 extends from the first side plate 11 towards the second side plate 12. The first side plate 11 defines a plurality of air inlets 111 and a plurality of air outlets 113. The partition 110 is located between the plurality of air inlets 111 and the plurality of air outlets 113. In one embodiment, the partition 110 is substantially perpendicular to the first side plate 11.

The cooling module 100 includes a fan 20, a fin assembly 30, and a plurality of heat pipes 50. The fan 20 defines a fan inlet 21 and a fan outlet 23. A part of each of the plurality of heat pipes 50 is secured to the fin assembly 30.

In assembly, the cooling module 100 is mounted in the receiving space 16, the fin assembly 30 is adjacent to the plurality of air outlets 113 between the partition 110 and the third side plate 13. The fan outlet 23 faces the fin assembly 30 and the plurality of air outlets 113 and is located between the partition 110 and the third side plate 13. A length of the partition 110 is greater than a distance between the fan outlet 23 and first side plate 11.

In use, air flows into the chassis 10 through the plurality of air inlets 111 along a first direction and flows out of the plurality of air outlets 113 along a second direction via the fan inlet 21 and the fan outlet 23 under the action of the fan 20, and then the fin assembly 30 and the electronic device is cooled. The first direction is substantially parallel to and opposite to the second direction. The partition 110 separates the plurality of air inlets 111 from the plurality of air outlets 113, to prevent air from flowing from the plurality of air inlets 111 to the plurality of air outlets 113 directly.

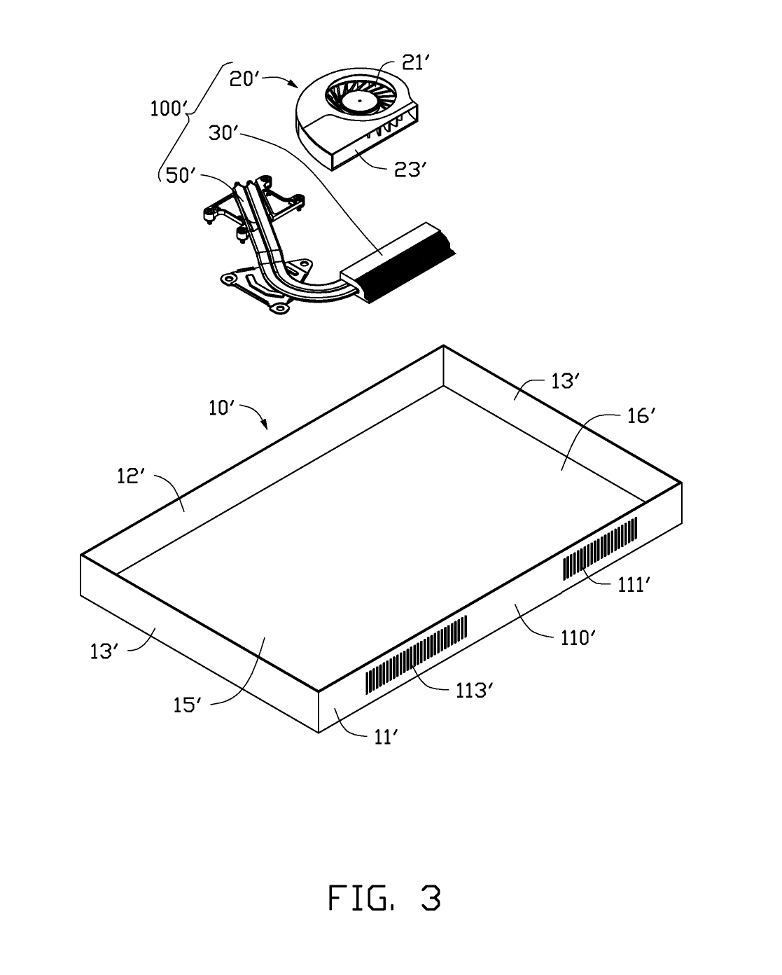

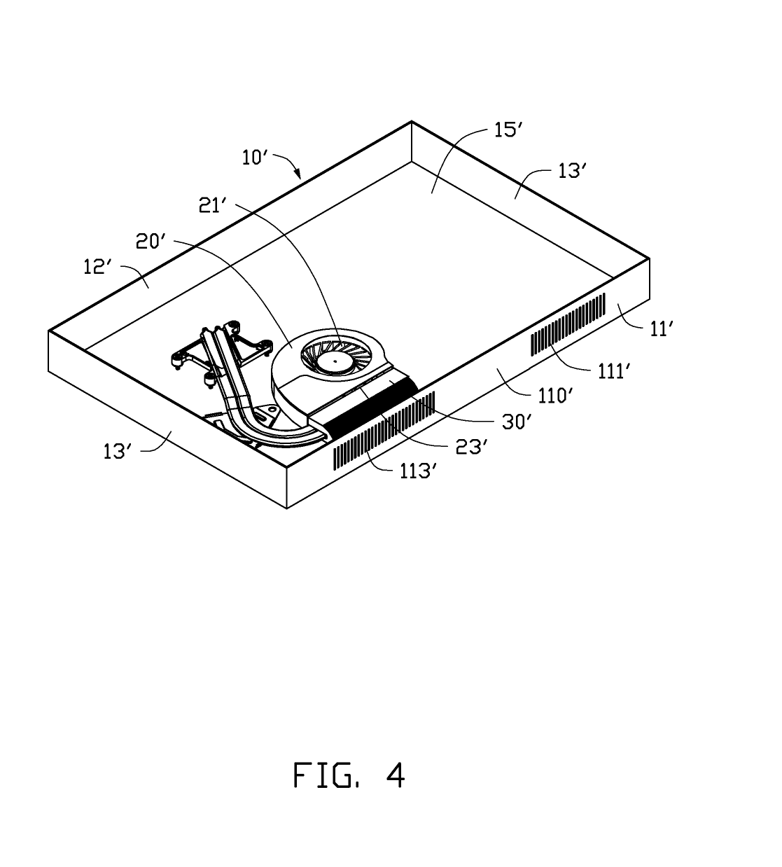

FIG. 3 and FIG. 4 show the electronic device in accordance with another embodiment. The electronic device includes a chassis 10′ and a cooling module 100′.

The chassis 10′ includes a first side plate 11′, a second side plate 12′, two third side plates 13′, and a bottom plate 15′. The first side plate 11′, the second side plate 12′, and the two third side plates 13′ perpendicularly extend from four edges of the bottom plate 15′. In one embodiment, the first side plate 11′ is substantially parallel to the second side plate 12′, and the first side plate 11′ is substantially perpendicular to each of the two third side plates 13′. A receiving space 16′ is defined cooperatively by the first side plate 11′, the second side plate 12′, and the two third side plates 13′. The receiving space 16′ is used for receiving electronic components, such as the cooling module 100′ and a circuit board (not shown).

The first side plate 11′ defines a plurality of air inlets 111′ and a plurality of air outlets 113′ and includes a partition 110′. The partition 110′ is located between the plurality of air inlets 111′ and the plurality of air outlets 113′. In one embodiment, the partition 110′ is substantially perpendicular to the first side plate 11′. The partition 110′ separates the plurality of air inlets 111′ from the plurality of air outlets 113′. In one embodiment, a length of the partition 110′ is greater than a quarter of a length of the first side plate 11′.

The cooling module 100′ includes a fan 20′, a fin assembly 30′, and a plurality of heat pipes 50′. The fan 20′ defines a fan inlet 21′ and a fan outlet 23′. Apart of each of the plurality of heat pipes 50′ is secured to the fin assembly 30′.

In assembly, the cooling module 100′ is mounted in the receiving space 16′, the fin assembly 30′ is adjacent to the plurality of air outlets 113′. The fan outlet 23′ faces the fin assembly 30′ and the plurality of air outlets 113′. The length of the partition 110 is greater than a distance between the fan outlet 23′ and first side plate 11′.

In use, air flows into the chassis 10′ through the plurality of air inlets 111′ along a first direction and flows out of the plurality of air outlets 113′ along a second direction via the fan inlet 21′ and the fan outlet 23′ under the action of the fan 20′, and then the fin assembly 30′ and the electronic device is cooled. The first direction is substantially parallel to and opposite to the second direction. The partition 110′ separates the plurality of air inlets 111′ from the plurality of air outlets 113′, to prevent air from flowing from the plurality of air inlets 111′ to the plurality of air outlets 113′ directly.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device with a cooling module comprising:
a chassis comprising a first side plate and a partition located on the first side plate; and
a cooling module comprising a fan defining a fan inlet and a fan outlet;
wherein the first side plate define a plurality of air inlets and a plurality of air outlets, and the partition separates the plurality of air inlets from the plurality of air outlets; the fan outlet faces the plurality of air outlets; and an air path is defined by the plurality of air inlets, the fan inlet, the fan outlets, and the plurality of air outlets.

2. The electronic device with a cooling module of claim 1, wherein the air path is configured for air flowing into the chassis through the plurality of air inlets along a first direction and air flowing out of the chassis through the plurality of air outlets along a second direction, and the first direction is opposite and substantially parallel to the second direction.

3. The electronic device with a cooling module of claim 1, wherein the partition is substantially perpendicular to the first side plate.

4. The electronic device with a cooling module of claim 3, wherein a length of the partition is greater than a distance between the fan outlet and the first side plate.

5. The electronic device with cooling module of claim 1, wherein the partition and the first side plate are coplanar.

6. The electronic device with a cooling module of claim 5, wherein a length of the partition is greater than a quarter of a length of the first side plate.

7. The electronic device with a cooling module of claim 1, wherein the cooling module further comprises a fin assembly, and the fin assembly is adjacent to the plurality of air outlets and located in a side of the partition.

8. The electronic device with a cooling module of claim 7, wherein the fin assembly is located between the fan outlet and the plurality of air outlets.

9. The electronic device with a cooling module of claim 7, wherein the cooling module further comprises a heat pipe, and a part of the heat pipe is secured to the fin assembly.

10. An electronic device with a cooling module comprising:
a chassis comprising a first side plate and a partition located on the first side plate; and
a cooling module comprising a fin assembly and a fan defining a fan inlet and a fan outlet;
wherein the first side plate defines a plurality of air inlets and a plurality of air outlets, and the partition is located between the plurality of air inlets and the plurality of air outlets and separates the plurality of air inlets and the plurality of air outlets; the fin assembly is located between the fan outlet and the plurality of air outlets; and an air path is defined by the plurality of air inlets, the fan inlet, the fan outlets, and the plurality of air outlets.

11. The electronic device with a cooling module of claim 10, wherein the air path is configured for air flowing into the chassis through the plurality of air inlets along a first direction and air flowing out of the chassis through the plurality of air outlets along a second direction, and the first direction is opposite and substantially parallel to the second direction.

12. The electronic device with a cooling module of claim 10, wherein the partition is substantially perpendicular to the first side plate.

13. The electronic device with a cooling module of claim 12, wherein a length of the partition is greater than a distance between the fan outlet and the first side plate.

14. The electronic device with a cooling module of claim 10, wherein the partition and the first side plate are coplanar.

15. The electronic device with a cooling module of claim 14, wherein a length of the partition is greater than a quarter of a length of the first side plate.

16. The electronic device with a cooling module of claim 10, wherein the fin assembly faces the plurality of air outlets and located in a side of the partition.

17. The electronic device with a cooling module of claim 10, wherein the cooling module further comprises a heat pipe, and a part of the heat pipe is secured to the fin assembly.
